(19) United States
(12) Patent Application Publication
(10) Pub. No.: US 2008/0074850 A1
(43) Pub. Date: Mar. 27, 2008

(54) MOUNTING APPARATUS FOR EXPANSION CARD

(75) Inventor: SZU-WEI KUO, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/760,801

(22) Filed: Jun. 11, 2007

(30) Foreign Application Priority Data
Sep. 27, 2006 (CN) 200620200802.8

(51) Int. Cl. H05K 1/14

(52) U.S. Cl. 361/740; 361/683; 361/737; 439/327

(57) ABSTRACT

A mounting apparatus for fixing an expansion card to a motherboard, includes a connector socket for engaging with a first portion of the expansion card, and a clamp configured for engaging with a second portion of the expansion card. The connector socket is installed on the motherboard, and two latching portions are formed on two sides of the connector socket respectively. The clamp includes two elastic arms riding on the second portion of the expansion card and engaging with the corresponding latching portions of the connector socket.

### BACKGROUND OF THE INVENTION

1. Field of the Invention

The present invention relates to mounting apparatuses, and more particularly to a mounting apparatus for an expansion card.

2. Description of Related Art

Computer systems typically require or include expansion cards which extend the capabilities of computer systems by providing dedicated hardware to achieve a variety of tasks. A conventional expansion card includes a main body electrically connectable with a motherboard in a computer chassis, and a generally L-shaped stop plate installable on a rear plate of the computer chassis. The stop plate is typically installed on the rear plate by a screw. However, if the screw is not properly fastened, the expansion card is easy to come adrift or be tilted, if a distal end of the expansion card should accidentally impact something, the motherboard or the expansion card may be damaged.

What is needed, therefore, is a mounting apparatus which facilitates the convenient and secure mounting of an expansion card.

### SUMMARY OF THE INVENTION

A mounting apparatus is supplied for fixing an expansion card to a motherboard. The mounting apparatus includes a connector socket for engaging with a first portion of the expansion card, and a clamp configured for engaging with a second portion of the expansion card. The connector socket is installed on the motherboard, and two latching portions are formed on two sides of the connector socket respectively. The clamp includes two elastic arms riding on the second portion of the expansion card and engaging with the corresponding latching portions of the connector socket.

Other advantages and novel features will become more apparent from the following detailed description of preferred embodiment when taken in conjunction with the accompanying drawings, in which:

### BRIEF DESCRIPTION OF THE DRAWINGS

FIG. 1 is an exploded, isometric view of a mounting apparatus together with a computer chassis and an expansion card in accordance with a preferred embodiment of the present invention, the mounting apparatus includes a connector socket, and a clamp;

FIG. 2 is a partially assembled view of FIG. 1 without the clamp; and

FIG. 3 is an assembled view of FIG. 1.

### DETAILED DESCRIPTION OF THE INVENTION

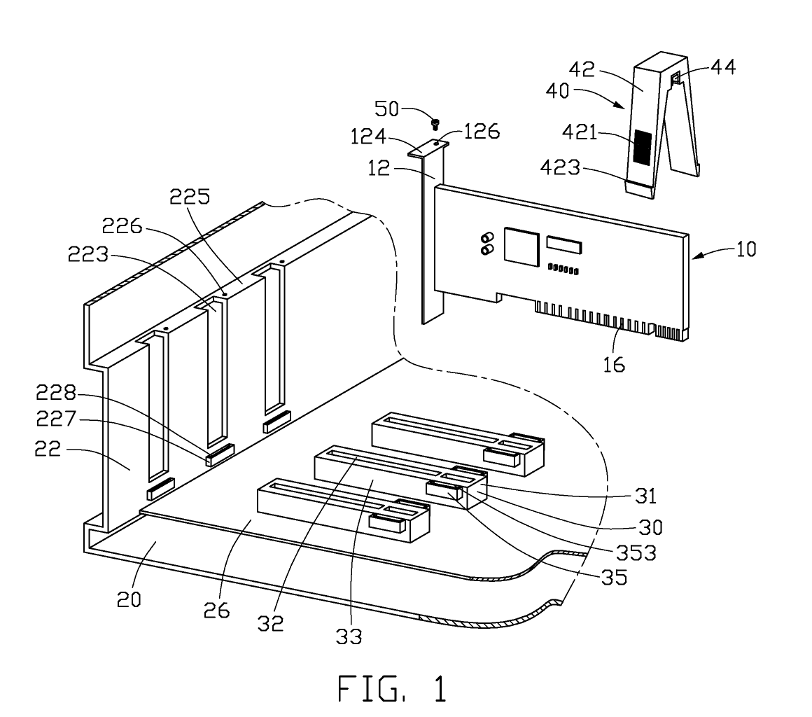

Referring to FIG. 1, a mounting apparatus is provided in accordance with an embodiment of the present invention, for fixing an expansion card 10 or more expansion cards 10 in a computer chassis 20. The mounting apparatus includes at least one connector socket 30, and at least one inverted V-shaped clamp 40.

A plurality of horizontally spaced pins 16 is formed on a bottom portion of the expansion card 10. A stop plate 12 is attached to an end of the expansion card 10, and a fixing portion 124 defining a through hole 126 therein is bent perpendicularly from a top of the stop plate 12 in a direction away from the expansion card 10.

The computer chassis 20 includes a rear plate 22, and a supporting plate 225 is bent perpendicularly outward from the rear plate 22. For each expansion card 10 to be installed, the supporting plate 225 and the rear plate 22 together define an L-shaped aperture 223, corresponding to the stop plate 12 of the expansion card 10. A bridge 227 is formed on an inside surface of the rear plate 22 below each aperture 223, and therefore a through slot 228 is formed between the bridge 227 and the rear plate 22. A fixing hole 226 is defined in the supporting plate 225, corresponding to the through hole 126 of the stop plate 12 of each expansion card 10.

A motherboard 26 is installed in the computer chassis 20 neighboring the rear plate 22, and the connector sockets 30 are mounted on the motherboard 26. Each connector socket 30 includes a main body 31, and an expansion slot 32 is defined in the connector socket 30 for receiving and electrically connecting with the pins 16 of the expansion card 10. The connector socket 30 includes two parallel sidewalls 33, each sidewall 33 forms a latching portion 35 outward on a section thereof away from the rear plate 22 of the computer chassis 20, and a latching slot 353 is defined downward between each sidewall 33 of the connector socket 30 and its corresponding latching portion 35.

The clamp 40 includes two elastic arms 42 extending out slantingly from a junction thereof, and a hooking portion 423 is formed outward from a free end of each elastic arm 42. A plurality of ribs 421 is formed on an outside surface of each elastic arm 42. A recess 44 is defined in the junction in communication with a space defined by inside surfaces of the elastic arms 42, and a skidproof gasket may be attached to the recess 44 for firmly engaging with the expansion card 10.

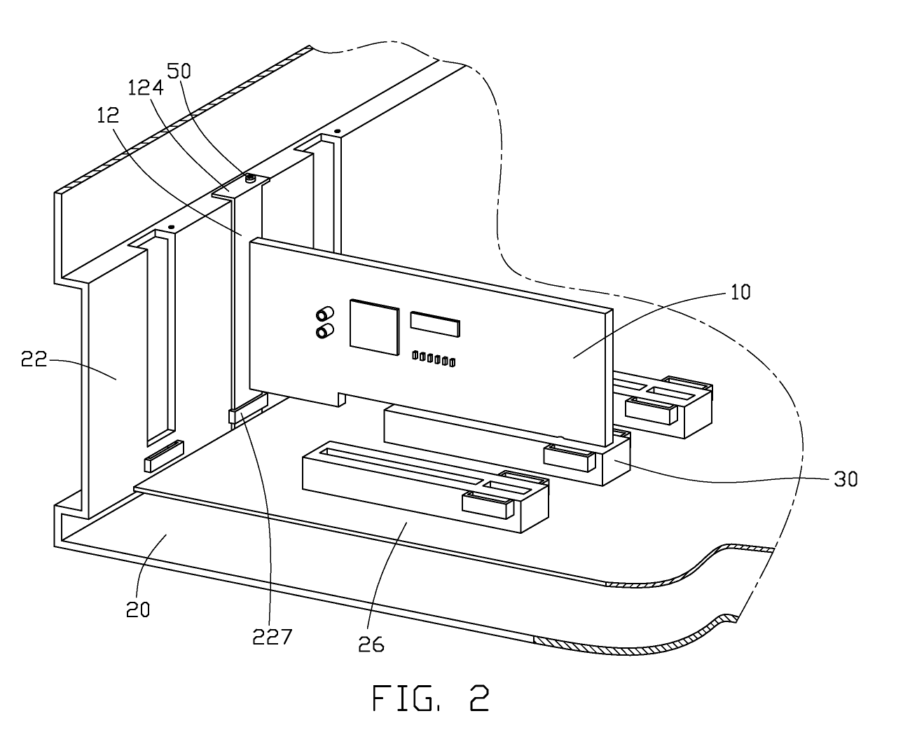

Referring also to FIG. 2, in assembly the expansion card 10, a bottom portion of the stop plate 12 of the expansion card 10 extends through the through slot 228 between the rear plate 22 and the bridge 227 of the computer chassis 20, and the pins 16 of the expansion card 10 are inserted into the expansion slot 32 of the connector socket 30 on the motherboard 26. The stop plate 12 covers a vertical portion of the aperture 223 of the rear plate 22, and the fixing portion 124 of the stop plate 12 is disposed on the supporting plate 225 and covers a horizontal portion of the aperture 223 of the supporting plate 225. The through hole 126 of the fixing portion 124 aligns with the fixing hole 226 of the supporting plate 225. A screw 50 is extended through the through hole 126 of the fixing portion 124 and engaged in the fixing hole 226 of the supporting plate 225, thereby the stop plate 12 is fixed to the computer chassis 20.

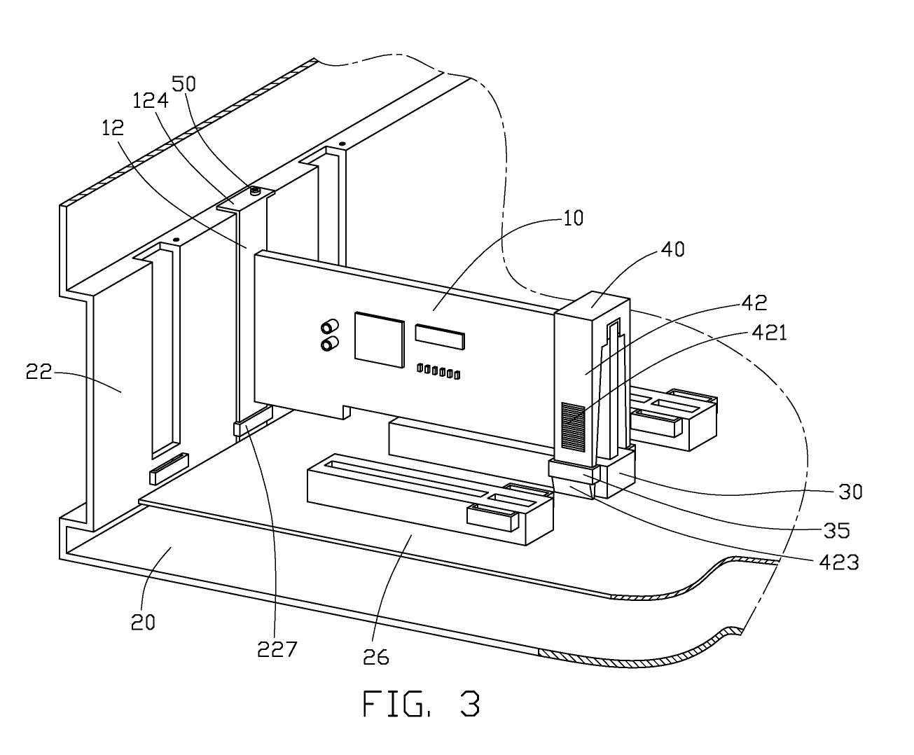

Referring further to FIG. 3, the elastic arms 42 of the clamp 40 are pressed toward each other to allow the hooking portions 423 extend through the latching slots 353 of two sides of the connector socket 30 respectively. A top portion of the expansion card 10 engages in the recess 44 and abuts against the skidproof gasket of the clamp 40. When the elastic arms 42 are released and thereby restored, the hooking portions 423 of the elastic arms 42 of the clamp 40 engage with the bottom portions of the corresponding latching portions 35 of the connector socket 30, thereby the expansion card 10 is firmly mounted in the computer chassis 20.

To detach the expansion card 10 from the computer chassis 20, the elastic arms 42 of the clamp 40 are pressed toward each other to allow the hooking portions 423 to disengage from the corresponding latching portions 35 of the connector socket 30 and thereafter exit the latching slots 353, thereby the clamp 40 is detached. The screw 50 is disengaged to allow the stop plate 12 of the expansion card 10 to be pulled up. The pins 16 of the expansion card 10 disengage from the expansion slot 32 of the connector socket 30, thereby the expansion card 10 is detached.

It is believed that the present embodiment and its advantages will be understood from the foregoing description, and it will be apparent that various changes may be made thereto without departing from the spirit and scope of the invention or sacrificing all of its material advantages, the example hereinbefore described merely being preferred or exemplary embodiment of the invention.

What is claimed is:

1. A mounting apparatus for fixing an expansion card to a motherboard, the mounting apparatus comprising:
a connector socket fixed on the motherboard configured for engagingly receiving a first portion of the expansion card, and two latching portions formed on two sides of the connector socket respectively; and
a clamp configured for engaging with a second portion of the expansion card, the clamp comprising two elastic arms for engaging with the corresponding latching portions of the connector socket.

2. The mounting apparatus as claimed in claim 1, wherein a latching slot is defined between the connector socket and each of the latching portions, each of the elastic arms forms a hooking portion outward, configured for extending through the corresponding latching slot and engaging with a corresponding latching portion.

3. The mounting apparatus as claimed in claim 1, wherein the clamp is inverted V-shaped.

4. The mounting apparatus as claimed in claim 1, wherein a recess is defined in a junction of the elastic arms for engaging with the second portion of the expansion card.

5. The mounting apparatus as claimed in claim 4, wherein a skidproof gasket is attached to the recess for firmly engaging with the expansion card.

6. The mounting apparatus as claimed in claim 1, wherein a plurality of ribs is formed on an outside surface of each of the elastic arms.

7. A mounting apparatus for fixing an expansion card to a motherboard, the mounting apparatus comprising:
a connector socket installable on the motherboard and configured for engaging with the expansion card; and
a clamp comprising two arms and configured for riding on the expansion card, with the arms engaging with the connector socket and being positioned adjacent opposite sides of the expansion card, and at least one of the arms spaced apart from one of the opposite sides of the expansion card when the expansion card is firmly fixed to the motherboard and being deflectable toward the one of the opposite sides of the expansion card when an external force exerted thereon to disengage from the connector socket.

8. The mounting apparatus as claimed in claim 7, wherein two latching portions are formed on two sides of the connector socket respectively, for engaging with the arms of the clamp respectively.

9. The mounting apparatus as claimed in claim 8, wherein a latching slot is defined between the connector socket and each of the latching portions, each of the arms forms a hooking portion outward, configured for extending through the corresponding latching slot and engaging with a corresponding latching portion.

10. The mounting apparatus as claimed in claim 7, wherein the clamp is inverted V-shaped.

11. The mounting apparatus as claimed in claim 7, wherein a recess is defined in a junction of the arms for engaging with a top portion of the expansion card.

12. The mounting apparatus as claimed in claim 10, wherein a skidproof gasket is attached to the recess for firmly engaging with the expansion card.

13. The mounting apparatus as claimed in claim 7, wherein a plurality of ribs is formed on an outside surface of each of the arms.

14. The mounting apparatus as claimed in claim 7, further comprising a computer chassis forming a plate configured for fixing one end of the expansion card.

15. The mounting apparatus as claimed in claim 14, wherein the expansion card comprises a stop plate attached to the plate of the computer chassis, and a bridge is formed on an inside surface of the plate for securing the stop plate.

16. A mounting apparatus assembly comprising:
a chassis comprising a motherboard mounted therein, and a panel perpendicular to the motherboard, the panel defining a plurality of slots perpendicular to the motherboard, a supporting plate extending outward from the panel;
a connector socket installed on the motherboard;
an expansion card comprising a stop plate formed at one lateral side thereof, the stop plate comprising a fixing portion bent perpendicularly from the stop plate and securely seated on the supporting plate, one portion of a longitudinal side of the expansion card being received in the connector socket; and
a clamp comprising two arms riding on an opposite longitudinal side of the expansion card away from the connector socket, each of the arms comprising a hooking portion engaging with the connector socket in a direction perpendicular to the motherboard, the arms being deflectable in another direction parallel to the motherboard to disengage the hooking portion from the connector socket.

17. The mounting apparatus assembly as claimed in claim 16, wherein two latching portions are formed on two sides of the connector socket respectively, a latching slot is defined between the connector socket and each of the latching portions, and the hooking portions extend through the corresponding latching slots and engage with the corresponding latching portions.

18. The mounting apparatus assembly as claimed in claim 16, wherein the clamp defines a recess in a junction between the arms, the opposite longitudinal side of the expansion card being received in the recess.

19. The mounting apparatus assembly as claimed in claim 16, wherein the clamp is positioned adjacent an opposite lateral side of the expansion card away from the panel.
